(19) United States
(12) Patent Application Publication
(10) Pub. No.: US 2020/0013629 A1
(43) Pub. Date: Jan. 9, 2020

(54) SEMICONDUCTOR PROCESSING APPARATUS

(71) Applicant: ASM IP Holding B.V., Almere (NL)

(72) Inventors: David Kurt de Roest, Kessel-Lo (BE); Werner Knaepen, Leuven (BE); Krzysztof Kachel, Heverlee (BE)

(21) Appl. No.: 16/468,258

(22) PCT Filed: Dec. 8, 2017
(86) PCT No.: PCT/IB2017/001644

§ 371 Date: Jun. 10, 2019

Related U.S. Application Data
(60) Provisional application No. 62/434,955, filed on Dec. 15, 2016.

(51) Int. Cl. H01L 21/3065; H01L 21/02; H01L 21/324

(52) U.S. Cl. CPC H01L 21/3065; H01L 21/324; H01L 21/02175; H01L 21/02255

(57) ABSTRACT

An apparatus and a method for forming a structure within a semiconductor processing apparatus are disclosed. The apparatus includes a first reaction chamber, the first reaction chamber configured to hold at least one substrate having a first layer. The apparatus also includes a precursor delivery system configured to perform an infiltration by sequentially pulsing a first precursor and a second precursor on the substrate. The apparatus may also include a first removal system configured for removing at least a portion of the first layer disposed on the substrate while leaving an infiltrated material, wherein the infiltration and the removing at least a portion of the first layer take place within the same semiconductor processing apparatus. A method of forming a structure within a semiconductor processing apparatus is also disclosed, the method including providing a substrate for processing in a reaction chamber, the substrate having a first layer disposed on the substrate. The method may also include performing a first layer infiltration by sequentially pulsing a first precursor and a second precursor on the substrate, wherein an infiltrated material forms in the first layer from the reaction of the first precursor and the second precursor. The method may also include removing at least a portion of the first layer disposed on the substrate after performing the infiltration, wherein the infiltration and the removing at least a portion of the first layer take place with the same semiconductor processing apparatus.

### CROSS-REFERENCE TO RELATED APPLICATION

This application claims the benefit of U.S. Provisional Application No. 61/434,955, filed on Dec. 15, 2016, the disclosure of which is hereby incorporated herein by reference.

### FIELD OF INVENTION

The present disclosure generally relates to apparatus for manufacturing electronic devices. More particularly, the disclosure relates to semiconductor processing apparatus configured to form a structure.

### BACKGROUND OF THE DISCLOSURE

As the trend has pushed semiconductor devices to smaller and smaller sizes, different patterning techniques have arisen. These techniques include self-aligned multiple patterning, spacer defined quadruple patterning, deep ultraviolet lithography (DUV), extreme ultraviolet lithography (EUV), and DUV, EUV combined with Spacer Defined Double patterning. In addition, directed self-assembly (DSA) has been considered as an option for future lithography applications. DSA involves the use of block copolymers to define patterns for self-assembly. The block copolymers used may include poly(methyl methacrylate) (PMMA), polystyrene, or poly(styrene-block-methyl methacrylate) (PS-b-PMMA). Other block copolymers may include emerging “high-Chi” polymers, which may potentially enable small dimensions. These approaches have allowed production of nodes in the 7 nm range.

The patterning techniques described above may utilize at least one polymer resist disposed on a substrate to enable high resolution patterning of the substrate. To satisfy the requirements of both high resolution and line-edge roughness, the polymer resist may commonly be a thin layer. However, such thin polymer resists may have several drawbacks. In particular, high resolution polymer resists, such as PMMA or polystyrene may have low etch resistance. This low etch resistance makes the transfer of the patterned resist to underlying layers more difficult. The issue of low etch resistance becomes greater when the advanced high resolution polymer resists needed to further downscale the size of the semiconductor device has an even lower etch resistance and etch selectivity. In addition, the high resolution polymer resists may result in high edge roughness in the obtained patterns.

In some applications, it may be advantageous to transfer the pattern of the polymer resist to a hardmask. A hardmask is a material used in semiconductor processing as an etch mask instead of the polymer or other organic “soft” resist materials with a higher etching resistance and etching selectivity. However, even a hardmask may have an etch rate, line edge roughness or a line width which needs to be adjusted.

As a result, a polymer resist and hardmask system with advanced properties may be desired.

### SUMMARY OF THE DISCLOSURE

In accordance with at least one embodiment of the invention, a semiconductor processing apparatus configured to form a structure is disclosed. The semiconductor processing apparatus may comprise: a first reaction chamber, the first reaction chamber configured to hold at least one substrate having a first layer. The apparatus may also comprise a precursor delivery system, the precursor delivery system configured to perform an infiltration by sequentially pulsing a first precursor and a second precursor onto the at least one substrate, to enable infiltration of at least the first precursor and the second precursor into the first layer from the reaction of the first precursor and the second precursor, thereby forming an infiltrated material. The semiconductor processing apparatus may also comprise a first removal system configured for removing at least a portion of the first layer disposed on the substrate while leaving the infiltrated material, wherein the infiltration and the removing at least a portion of the first layer take place within the same semiconductor processing apparatus.

In accordance with at least one embodiment of the invention, a method of forming a structure within a semiconductor processing apparatus is disclosed. The method may comprise: providing a substrate for processing in a reaction chamber, the substrate having a first layer disposed on the substrate. The method may also comprise, performing a first layer infiltration by sequentially pulsing a first precursor and a second precursor onto the substrate, the first layer infiltration being configured to enable infiltration of at least the first precursor and the second precursor into the first layer, wherein an excess of the first precursor and the second precursor are purged from the reaction chamber, and wherein an infiltrated material forms in the first layer from the reaction of the first precursor and the second precursor. The method may also comprise, removing at least a portion of the first layer disposed on the substrate after performing the infiltration while leaving the infiltrated material, wherein the infiltration and the removing at least a portion of the first layer take place within the same semiconductor processing apparatus.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a flowchart in accordance with at least one embodiment of the invention.

FIG. 2 illustrates an exemplary semiconductor processing apparatus in accordance with various exemplary embodiments of the disclosure.

FIG. 3 illustrates an additional exemplary semiconductor processing apparatus in accordance with various exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof Thus, it is intended that the scope of the invention disclosed should not be limited by the particular disclosed embodiments described below.

In addition, although a number of example materials are given throughout the embodiments of the current disclosure, it should be noted that the chemical formulas given for each of the example materials should not be construed as limiting and that the non-limiting example materials given should not be limited by a given example stoichiometry.

As used herein, the term “structure” may comprise both patterned and non-patterned (i.e., planar) layers of one or more materials.

Embodiments in accordance with the disclosure relate to the combination of high resolution polymer resists and hardmask materials with infiltration processes. This combination of polymer resists and hardmask materials with infiltration processes can increase the etch resistance of polymers resists and hardmask materials significantly. Infiltration techniques allow for high resolution polymer resists and hardmasks to be reacted with a precursor gas to improve etch resistance, and subsequent processes can remove unwanted portions of the high resolution polymer resist and hardmask material utilizing an etchant gas.

Combining infiltration processes with high resolution polymer and hardmask patterning may provide benefits previously unseen with prior approaches, such as the one described in U.S. Patent Publication No. US20140273514A1. For example, an infiltration of aluminum oxide (Al₂O₃) at 90° C. may allow the reaction with a high resolution polymer resist. The aluminum oxide will not only form on top of the high resolution polymer resist, but may be infused into the polymer to increase the rigidity of the polymer.

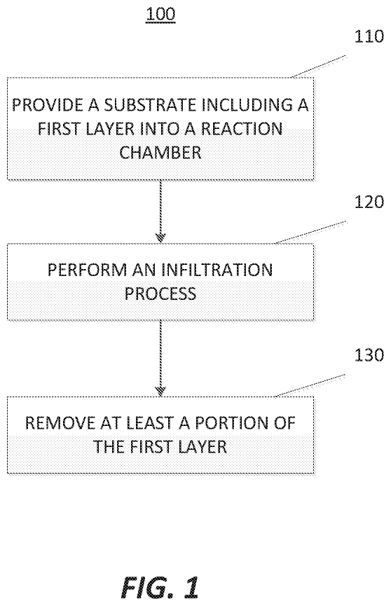

FIG. 1 illustrates a method 100 in accordance with at least one embodiment of the invention. The method 100 includes a first step 110 of providing a substrate into a semiconductor processing apparatus, the substrate having a first layer disposed upon the substrate.

In some embodiments of the disclosure, the first layer may comprise at least one of a high resolution polymer resist or a hardmask material. In greater detail, in some embodiments, the first layer may comprise a high resolution polymer resist comprising at least one of poly(methyl methacrylate) (PMMA), polystyrene, poly(styrene-block-methyl methacrylate) (PS-b-PMMA), deep UV photoresist, 193 nm photoresist (both immersion (193i) and non-immersion (193)) and extreme UV photoresist. In some embodiments of the disclosure, the first layer may comprise a first component and a second component wherein the first component may have at least a first DSA polymer and second component may have a second DSA polymer, wherein the first DSA polymer and the second DSA polymer may be made of PMMA, polystyrene (PS), among other polymers. In some embodiments of the disclosure, the first layer may comprise a hardmask material further comprising at least one of a spin-on-glass, a spin-on-carbon layer, a silicon nitride layer, an anti-reflective-coating layer or an amorphous carbon layer. The spin-on-glass or spin-on-carbon layer may be provided by spinning a glass or carbon layer on the substrate to provide the hardmask material.

In some embodiments, the semiconductor processing apparatus may be a batch reactor (e.g., a single reaction chamber) or a cluster tool with two batch reactors (e.g., two or more reaction chambers). One example of a potential semiconductor processing apparatus may include a processing chamber, which may run in two reaction chambers the same process or run two different processes independently or sequentially. In some embodiments, the semiconductor processing apparatus may be a single-wafer reactor (e.g., a single reaction chamber) or a cluster tool with two single-wafer reactors (e.g., two or more reaction chambers). One example of a potential processing chamber may include a processing chamber, which may run in two or more single-wafer reaction chambers the same process or run two different processes independently or sequentially.

In some embodiments, wherein the first layer disposed on the substrate comprises a block copolymer, the method 100 may also include performing a self-assembly anneal of the DSA polymers. The purpose of the annealing process is to incite the self-assembly or self-organization in the DSA polymers or the block copolymer. In other words, parallel lines or grids of holes/pillars/posts in the polymers may be formed as directed by guidance structures on the substrate. In accordance with at least one embodiment of the invention, this may mean that domains of PMMA and domains of PS may be formed in an alternating manner. The benefits achieved by the self-assembly anneal may include improvement of the self-assembly process, reduction of defects, improved line width roughness, and improved critical dimension (CD) uniformity.

In alternative embodiments, the first layer may comprise a high resolution polymer resist which may not comprise a block copolymer and the anneal step may have a purpose of degassing moisture or other contaminants from the polymer, hardening the polymer, or selectively burning away portions of the polymer from the substrate surface.

In embodiments in which a self-assembly anneal of a DSA polymer is performed in order to reach a low defect density in the obtained pattern, process parameters, such as the time, temperature, and the ambient conditions and pressure of the annealing process, may be critical. A long annealing time may be needed to obtain a low defect density. The anneal may take place at a temperature ranging between 100° C. and 400° C., or between 200° C. and 300° C., or at approximately 250° C. for about 60 minutes. Other temperatures and durations are possible depending on the amount of anneal desired. However, the temperature of the self-assembly anneal should not be increased too high or the polymers may start to decompose.

The ambient environment in which the annealing is done may comprise nitrogen, argon, helium, hydrogen, oxygen, ozone, water vapor, solvent vapors, or mixtures of these gases. The pressure of the anneal ambient environment can be any pressure in the range from ultra-high vacuum to atmospheric pressure or even above atmospheric pressure.

In accordance with one embodiment of the invention, the annealing process may take place on a single wafer hot plate. In accordance with another embodiment of the invention, a batch reactor may prove to be beneficial for processes needing a long anneal time. The batch reactor may hold between 2 and 250 substrates, preferably between 5 and 150 substrates, or most preferably about 100 substrates. For example, a cluster tool comprising two or more reaction chambers may be operated such that one reaction chamber may be used for an anneal process. This may enable performance of long anneals on the order of 1-2 hours in a cost effective way.

In some embodiments, the first step may also include an optional trimming process, wherein the trimming process may be performed to remove portions of the first layer prior to the subsequent processes of the disclosure. In some embodiments of the disclosure, the trimming process may comprise exposing the first layer to an excited plasma, such as, for example, a plasma comprising excited species of at least one of oxygen (O₂), nitrogen (N₂), ozone (O₃), and hydrogen (H₂). In some embodiments of the disclosure, the trimming process may comprise exposing the first layer to ozone without plasma. As a non-limiting example embodiment, the trimming process may comprise exposing the first layer to a plasma comprising excited species of oxygen and nitrogen. As a non-limiting example embodiment, the trimming process may comprise exposing the first layer to a plasma comprising excited species of oxygen. In some embodiments, the plasma may also comprise additional species, for example, noble gases such as Ar. In an additional non-limiting example embodiment, the trimming process may comprise exposing the first layer to a plasma comprising excited species of hydrogen and nitrogen. In embodiments wherein the trimming process utilizes an excited plasma to remove a portion of the first layer, the first layer may be heated to a temperature of greater than about 20° C., or in some embodiments greater than about 50° C., or in some embodiments of the disclosure, the trimming process may comprise heating the first layer to a temperature of greater than approximately 100° C., or to a temperature of greater than approximately 200° C., or to a temperature greater than approximately 300° C., or even to a temperature greater than approximately 400° C.

In addition to and/or alternatively the trimming process may comprise a thermal process, such that a portion of the first layer may be removed by heating the first layer to a desired process temperature to promote decomposition of a portion of the first layer. In some embodiments of the disclosure, the trimming process may comprise heating the first layer to a temperature of greater than approximately 100° C., or to a temperature of greater than approximately 200° C., or to a temperature greater than approximately 300° C., or even to a temperature greater than approximately 400° C.

The method 100 may also include a second step 120 of performing an infiltration process, such as, for example infiltrating at least one of a metal or a dielectric film into the first layer. In some embodiments, the first layer may comprise at least one polymer layer which may further comprise either a first DSA polymer or a second DSA polymer. As such, the infiltration process may be done in a way that the infiltration process may react selectively with only one of the two polymers. For example, the infiltration process may take place such that the deposited film may react with PMMA polymer and not PS polymer.

In accordance with at least one embodiment of the invention, the second step 120 may comprise an atomic layer deposition of the metal or dielectric film.

Furthermore, the infiltration process may be done such that the deposited metal or dielectric film may infiltrate the first layer thereby forming an infiltrated material, while also depositing a second film on the whole volume of the first layer. In accordance with at least one embodiment of the invention, the second step 120 may take place in one reaction chamber of a cluster tool, such that the annealing step takes place in the another reaction chamber of the cluster tool. In accordance with at least one embodiment of the invention, the second step 120 may take place in one reaction chamber of a cluster tool, such that the trimming process takes place in another reaction chamber of the cluster tool. It may also be possible that the annealing step and the trimming process and the second step 120 take place in one single reaction chamber of either a batch reactor or a cluster tool. In addition, a substrate may transferred from a first reaction chamber to a second reaction chamber along with at least a second substrate in a multiple substrate holder. The multiple substrate holder may be capable of holding up 25 substrates or more, 50 substrates or more, 75 substrates or more, or 100 substrates or more.

The metal or dielectric infiltrated into the first layer in the second step 120 may comprise aluminum oxide (Al₂O₃), silicon dioxide (SiO₂), silicon nitride (SiN), silicon oxycarbide (SiOC), silicon carbonitride (SiCN), silicon (Si), aluminum nitride (AlN), titanium nitride (TiN), tantalum nitride (TaN), tungsten (W), cobalt (Co), titanium dioxide (TiO₂), titanium carbide (TiC), tantalum oxide (Ta₂O₅), zirconium dioxide (ZrO₂), or hafnium dioxide (HfO₂). In order to perform the infiltration process, precursors to obtain the metal may be used, such as trimethylaluminum (TMA) and water (H₂O) for the formation of Al₂O₃.

The infiltration process in the second step 120 may take place at a temperature ranging between 25° C. and 400° C., or at a temperature ranging between 60° C. and 90° C. for the formation of Al₂O₃. The temperature during the second step 120 may be less than the temperature during the optional annealing stage, so a cool down step may be needed to go from an example annealing temperature of 250° C. to a second step 130 temperature of 70° C. In accordance with at least one embodiment of the invention, a temperature of the optional annealing process is equal to or greater than that of the second step 120, or between 25° C. to 300° C. higher than that of the second step 120, or even between 100° C. to 250° C. higher than that of the second step 120.

The second step 120 may comprise a first pulse of a first precursor, such as TMA, for a duration ranging from 0.5 seconds to 10 minutes. The second step 120 may also then comprise a purge for a duration ranging from 10 to 60 seconds. The second step 120 may then comprise a pulse of a second precursor, such as water, for a duration ranging from 10 to 60 seconds. The second step 120 may then comprise a second purge having a duration ranging from 10 seconds to 2 minutes. In addition, the second step 120 may be repeated as needed in order to obtain sufficient infiltration of the metal or dielectric into the first layer disposed on the substrate.

In accordance with at least one embodiment of the invention, the second step 120 of infiltration may precede the optional step of annealing. In this case, the metal or dielectric film may first infiltrate the first layer, and then an annealing process may occur. As a result of the annealing process, portions of the first layer that did not react with the metal or dielectric film during the second step 120 may be burned away in the annealing step. In at least one embodiment of the invention, the optional annealing step and the second step 120 of infiltration take place without any exposure to ambient air. The lack of exposure to ambient air avoids exposure to substantial amounts of oxygen or water. Exposure to ambient air may adversely affect the alignment of the annealed pattern or infiltration of the polymer, which may be affected by the polymer potentially absorbing water. If the polymer absorbs water, deposition of undesired material may result.

The method 100 may also include an additional step of purging the precursors. The additional purging step may involve introduction of a purge gas such as nitrogen, helium, argon, and other inert gases. The purge gas would remove excess precursor from the reaction chamber. The purging step may take place at a temperature similar to those of the second step 120.

In accordance with at least one embodiment of the invention, the second step 120 may be repeated as necessary or desired in order to allow the precursors to infiltrate into the first layer. The cycle may be repeated approximately 1 or more times, 2 or more time, 3 or more times, 4 or more times, or even 5 or more times, to ensure sufficient amount of the metal or dielectric film in the first layer. In each cycle, the time duration of the second step 130 may be on the order of a few minutes. With these time durations, a batch reactor may be used to achieve high productivity and low process costs by processing up to 100 wafers or more at a time.

In accordance with at least one embodiment of the invention, the method 100 may be operated such that the second step 120 may be repeated in a pulse-purge-pulse-purge manner. The conditions of these steps may be set at higher pressure and a longer time in order to allow the precursors to infiltrate the first layer. A single cycle in this manner may range between 0.5 seconds and 120 minutes in duration, in some embodiments, a single cycle may range between 1 second and 60 minutes in duration, or even in some embodiments, a single cycle may range between 2 seconds and 20 minutes in duration. The cycle may be repeated several times, for example, in some embodiments, the cycle may be repeated 1 or more time, 2 or more times, 3 or more times, 4 or more times, or even 5 or more times, in order to obtain sufficient infiltration of the material inside the first layer. Because infiltration of the material inside the first layer may take a longer amount of time, a combined annealing and infiltration process provides an opportunity to perform steps in a batch manner.

The method 100 may also include a third step 130 of removing a portion of the first layer disposed on the substrate after performing the infiltration process. For example, in some embodiments, after the infiltration of the first layer, there may be remaining portions of the first layer which remain unaffected by the infiltration process. The portions of the first layer which remain unaffected by the infiltration process may be undesirable as these unaffected portions of the first layer may not be suitable for subsequent processes performed on the substrate, such as, for example, subsequent deposition or etch processes. Therefore embodiments of the disclosure may remove unwanted remaining portions of the first layer after infiltration but prior to subsequent processing of the substrate.

In some embodiments of the disclosure, the third step 130 of removing a portion of the first layer disposed on the substrate may comprise exposing the first layer to an etchant gas and in further embodiments exposing the first layer to an etchant gas may comprise exposing the first layer to an oxygen containing reactant. For example, the third step 130 of removing a portion of the first layer disposed on the substrate may comprise exposing the first layer to at least one of an oxygen containing plasma or an ozone containing reactant.

In embodiments utilizing an oxygen containing plasma to remove a portion of the first layer the methods may comprise utilizing a plasma generator to excite oxygen species for effective removal of portions of the first layer, a process sometimes referred to as “ashing.” The plasma generator may be supplied with oxygen (O₂) or alternatively a gas mixture of oxygen (O₂) and nitrogen (N₂). The etchant for removing a portion of the first layer may therefore comprise at least one of oxygen excited species and nitrogen excited species. In embodiments utilizing an oxygen containing plasma to remove a portion of the first layer, the first layer may be heated to a temperature of greater than about 20° C., or to a temperature of greater than about 50° C., or to a temperature of greater than about 100° C., or to a temperature of greater than about 200° C., or to a temperature of greater than about 300° C., or even to a temperature greater than about 400° C.

In some embodiments, utilizing an ozone containing reactant to remove a portion of the first layer the methods may comprise exposing the first layer to a gas mixture comprising ozone (O₃). In some embodiments, the gas mixture comprising ozone may consist of pure ozone, whereas in alternative embodiments the gas mixture comprising ozone may comprise ozone and at least one of water vapor, oxygen or an inert carrier gas.

In some embodiments, removing at least a portion of the first layer may comprise heating the first layer to a temperature of greater than approximately 100° C., or to a temperature of greater than approximately 150° C., or to a temperature of greater than approximately 200° C., or to a temperature greater than approximately 250° C., or to a temperature greater than approximately 300° C., or to a temperature greater than approximately 350° C., or even to a temperature greater than approximately 400° C. For example, as a non-limiting example, in embodiments wherein the first layer comprises a carbon containing material, such as a polymer resist or a spin-on-carbon layer, the portions of the first layer unaffected by the previous infiltration process may decompose at a temperature greater than approximately 300° C. and therefore may be removed without the need for additional etchants. In additional embodiments, the first layer may be heated to a temperature of greater than approximately 300° C. whilst being exposed to a solvent or ozone etchant.

In some embodiments, removing at least a portion of the first layer disposed on the substrate after performing the infiltration process further comprises selectively removing at least a portion of the first layer. In greater detail, a portion of the first layer may be infiltrated with at least the first precursor and the second precursor during the infiltration process, thereby forming an infiltrated material. Portions of the first layer which are unaffected by the infiltration processes are undesirable as previously described herein; the methods of the embodiments of the disclosure may therefore selectively remove those portions of the first layer which is unaffected by the infiltration process.

In accordance with an embodiment of the disclosure, the infiltration process and the removing at least a portion of the first layer may take place within the same reaction chamber. In alternative embodiments of the disclosure, the infiltration process and the removing at least a portion of the first layer may take place within different reaction chambers located on the same cluster tool, i.e., the same semiconductor processing apparatus, such that the infiltration process and the removing of at least a portion of the first layer take place without exposure to ambient air. In additional embodiments of the disclosure, the trimming process, the infiltration process and the removing at least a portion of the first layer may take place within the same reaction chamber. In alternative embodiments of the disclosure, the trimming process, the infiltration process and the removing at least a portion of the first layer may take place within different reaction chambers located on the same cluster tool, i.e., the same semiconductor processing apparatus, such that the trimming process, the infiltration process and the removing of at least a portion of the first layer take place without exposure to the ambient air.

The method of 100 may also include additional processes after the third step 130 of removing at least a portion of the first layer. For example, in some embodiments, the method 100 may further comprise at least one of a deposition process or an etching process on the substrate after removing at least a portion of the first layer disposed on the substrate. In greater detail, the remaining portion of the first layer which has under gone the infiltration processes may be utilized as a masking layer for etching a portion of the substrate, for example, by exposing the substrate to a plasma etching process. Alternatively, the remaining portion of the first layer which has under gone the infiltration process, i.e., the infiltrated material, may be utilized for a subsequent deposition process, for example, a deposition process may be utilized to deposit spacer material over the infiltrated material.

In accordance with an embodiment of the disclosure, the optional trimming process, the infiltration process, the removing at least a portion of the first layer and at least one of a deposition process or an etch process may take place within the same reaction chamber. In alternative embodiments of the disclosure, the optional trimming process, the infiltration process, the removing at least a portion of the first layer and at least one of a deposition process or an etch process may take place within different reaction chambers located on the same cluster tool, such that the optional trimming process, the infiltration, the removing of at least a portion of the first layer, and at least one of a deposition process or an etch process take place within the same semiconductor processing apparatus, i.e., without exposure to ambient air.

In some embodiments of the disclosure, the trimming process and the infiltration process may take place within the same reaction chamber with the process for removing at least a portion of the first layer being optional. In alternative embodiments of the disclosure, the trimming process and the infiltration process may take place within different reaction chambers located on the same cluster tool with the process for removing at least a portion of the first layer being optional. It should therefore be appreciated that both the trimming process and the infiltration process may be performed within the same semiconductor processing apparatus, i.e., without exposure to ambient air.

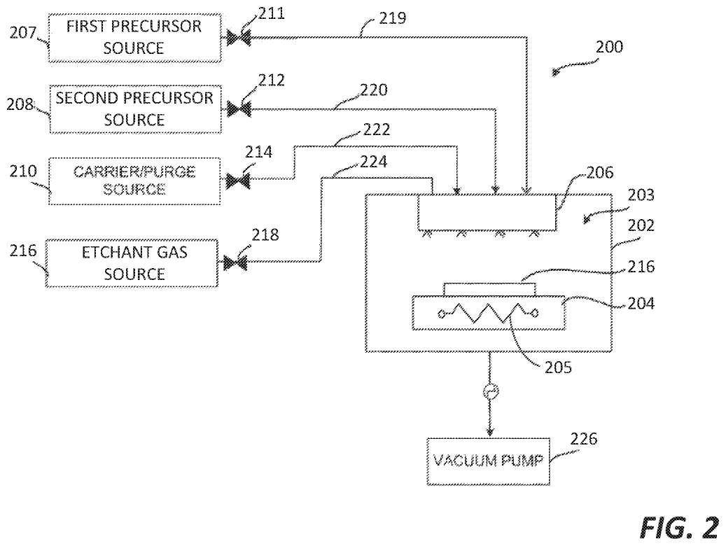

Turning now to FIG. 2, a semiconductor processing apparatus 200 for infiltration and removing at least a portion of a first layer is illustrated. The apparatus 200 may comprise a reactor 202 which may further comprise a first reaction chamber 203, a substrate holder 204, and a gas distribution system 206. The apparatus 200 may also comprise a precursor delivery system which may further comprise first precursor source 207; a second precursor source 208; a carrier or purge gas source 210. The apparatus 200 may comprise a first removal system configured for the optional trimming process and removing at least a portion of the first layer disposed on a substrate and the first removal system may further comprise an etchant gas source 216. The apparatus 200 may further comprise valves 211, 212, 214 and 218 interposed between the sources 207, 208, 210, 216 and reactor 202.

Reaction chamber 203 may be a standalone reaction chamber or part of a cluster tool. Further, reaction chamber 203 may be dedicated to an infiltration process as described herein, or reaction chamber 203 may be used for other processes, e.g., for film deposition, the trimming process, removing a portion of the first layer and one or more additional layer deposition and/or etch processing. For example, reaction chamber 203 may comprise a reaction chamber typically used for chemical vapor deposition (CVD) and/or atomic layer deposition (ALD) processing, and may also comprise direct plasma, and/or remote plasma apparatus. Further reaction chamber 203 may operate under a vacuum or near atmospheric pressure. By way of one example, reaction chamber 203 may comprise a reaction chamber suitable for ALD deposition of a film by sequentially pulsing the first precursor and the second precursor onto at least one substrate, the film being configured to enable infiltration of at least the first precursor and the second precursor into the first layer. An exemplary ALD reaction chamber suitable for semiconductor processing apparatus 200 is described in U.S. Pat. No. 8,152,922, the contents of which are hereby incorporated herein by reference, to the extent such contents do not conflict with the present disclosure.

Substrate holder 204 may be configured to hold at least one substrate, such as substrate 216, having a first layer disposed thereon, in place during processing. In accordance with various exemplary embodiments, the substrate holder 204 may form part of a direct plasma circuit. Additionally or alternatively, the substrate holder 204 may be heated (e.g., by heating element 205), cooled, or be at ambient process temperature during processing. In some embodiments, heating element 205 may be configured to perform an annealing step on the at least one substrate 216. In further embodiments, heating element 205 may be configured to remove a portion of the first layer.

Although gas distribution system 206 is illustrated in block form, the gas distribution system 206 may be relatively complex and designed to mix vapor (gas) from first precursor source 207, second precursor source 208, carrier/purge gas from gas source 210 and etchant gas source 216, prior to distributing the gas mixture to the remainder of reaction chamber 203. Further, gas distribution system 206 may be configured to provide vertical (as illustrated) or horizontal flow of gases to the semiconductor surface. An exemplary gas distribution system is described in U.S. Pat. No. 8,152,922.

First precursor source 207 may be a liquid, solid, or gas source of metal containing material suitable in a film deposition process. If first precursor source 207 is liquid or solid, the source material may be vaporized prior to entering the reaction chamber 203. In some embodiments of the disclosure, the first gas precursor may comprise at least one of trimethylaluminum (TMA), triethylaluminum (TEA), dimethylaluminumhydride (DMAH), titanium tetrachloride (TiCl₄), tantalum pentachloride (TaCl₅) or niobium pentachloride (NbCl₅).

Second precursor source 208 may be a liquid, solid, or gas source suitable in a film deposition process. If second precursor source 208 is liquid or solid, the source material may be vaporized prior to entering the reaction chamber 203. In some embodiments of the disclosure, the second precursor source may comprise at least one of water vapor, ozone, hydrogen peroxide, ammonia and hydrazine.

The first precursor source and the second precursor source may be utilized together to deposit a film being configured to enable infiltration of at least the first precursor source and the second precursor source into the first layer disposed on the substrate. For example, in some embodiments, the apparatus 200 may be configured to infiltrate a structure comprising at least one of aluminum oxide (Al₂O₃), silicon dioxide, (SiO₂), silicon nitride (SiN), silicon (Si), silicon oxynitride (SiON), silicon carbonitride (SiCN), aluminum nitride (AlN), titanium nitride (TiN), titanium carbide (TiC), tantalum nitride (TaN), tungsten (W), cobalt (Co), titanium dioxide (TiO₂), tantalum oxide (Ta₂O₅), zirconium dioxide (ZrO₂), or hafnium dioxide (HfO₂).

Carrier or purge gas source 210 may include any suitable gas suitable for mixing with the first precursor source 207 and/or the second precursor source 208. Carrier or purge gas source 210 may also include any suitable gas suitable for purging reaction chamber 203 before, after or during the infiltration process and the removing at least a portion of the first layer. In accordance with exemplary embodiments of the disclosure, a purge gas may be nitrogen, argon, helium, or a combination thereof. The carrier gas may also comprise nitrogen, argon, helium, or a combination thereof.

Semiconductor processing apparatus 200 may also include a first removal system which may further comprise etchant gas source 216, which includes solid, liquid or gas phase chemicals to enable the trimming process and remove at least a portion of the first layer disposed upon the substrate. For example, the etchant gas source 216 may include chemicals, which are gas-phase when entering reaction chamber 203, to remove at least a portion of the first layer disposed upon the substrate. As non-limiting example embodiments the etchant source 216 may include oxygen (O₂), ozone (0₃), nitrogen (N₂) and hydrogen (H₂). In some embodiments, the reaction chamber 203 and the first removal system includes a plasma generator configured to generate plasma activated species from an etchant gas supplied from the first removal system for forming excited species, for example, of oxygen and nitrogen.

As illustrated in FIG. 2, sources 207, 208, 210 and 216 are in fluid communication with reaction chamber 203 via valves 211, 212, 214 and 218, which may be used to control the flow, mixing and distribution of the respective source materials to reaction chamber 203 using the supply lines 219, 220, 222 and 224.

In additional embodiments, apparatus 200 may include one or more additional precursor sources which may be utilized for subsequent deposition of a film of material on the substrate after removing a portion of the first layer. In further additional embodiments, apparatus 200 may include one or more additional etchant gas sources which may be utilized for subsequent etching of the substrate after removing a portion of the first layer. Therefore, in some embodiments, the apparatus 200 may be configured to deposit a film, the film being configured to enable infiltration of at least the first precursor and the second precursor into the first layer disposed on the substrate, and removing at least a portion of the first layer wherein the infiltration and the removing at least a portion of the first layer take place within the same semiconductor processing apparatus, i.e., without exposing the substrate to ambient air.

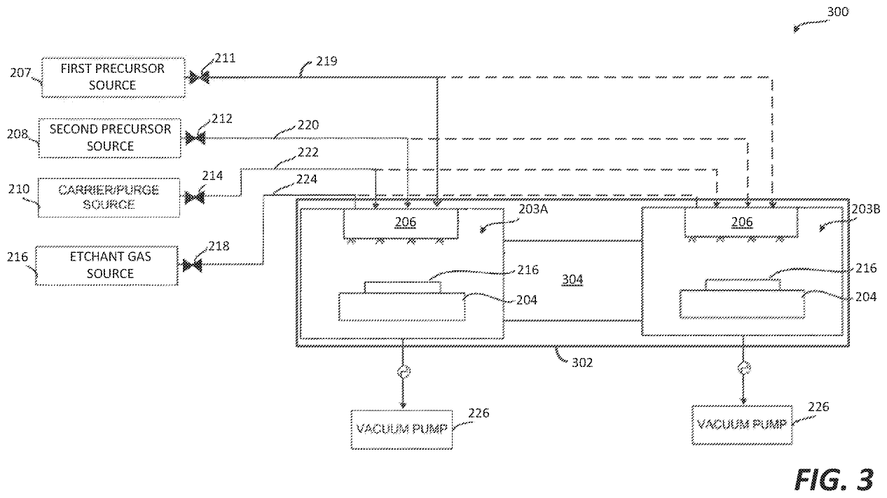

In additional embodiments of the disclosure, a semiconductor processing apparatus 300 for performing an optional trimming process, an infiltration process and removing at least a portion of a first layer is illustrated with reference to FIG. 3. The apparatus 300 may be similar to that of apparatus 200 but may comprise a reactor 302 which may further comprise a first reaction chamber 203A and a second reaction chamber 203B. In some embodiments, the reactor 302 comprises a cluster tool and although FIG. 3 illustrates a reactor 302 comprising two reaction chambers it should be appreciated that, in some embodiments, the reactor 302 may comprise a plurality of reaction chambers, wherein each reaction chamber comprises a substrate holder 204, and a gas distribution system 206, as previously described herein. The apparatus 300 may also comprise a first precursor source 207, a second precursor source 208, a carrier or purge gas source 210. The apparatus 300 may also comprise a first removal system further comprising etchant gas source 216. The apparatus 300 may also comprise valves 211, 212, 214 and 218 interposed between the sources 207, 208, 210, 216 and the reactor 302.

The apparatus 300 may also comprise a transfer system 304 utilized for transferring a substrate, e.g., a semiconductor, between the first reaction chamber 203A and the second reaction chamber 203B. The transfer system 304 may comprise a controlled environment such that the transfer of a substrate from the first reaction chamber 203A to the second reaction chamber 203B (and vice versa) may take place without exposure of the substrate to the ambient air.

In some embodiments, the reaction chamber 203A may be dedicated to a single process in the overall semiconductor process. For example, the reaction chamber 203A may be dedicated to performing an infiltration process by sequentially pulsing a first precursor and a second precursor onto substrate, whereas the second reaction chamber 203B may be dedicated to removing at least a portion of the first layer disposed on the substrate and/or an optional trimming process. It should be appreciated that, in some embodiments, the dedicated single processes in reaction chambers 203A and 203B may be reversed. The dedication of a single reaction chamber to one or more processes in the overall semiconductor process may allow for independent process parameters for each process comprising the overall semiconductor process, i.e., independent process parameters for the first reaction chamber 203A and the second reaction chamber 203B. For example, the first reaction chamber 203A may be controlled at a first temperature and first pressure whereas the second reaction chamber 203B may be controlled at a second temperature and a second pressure wherein the first temperature and the second temperature may be equal or different from one another and the first pressure and the second pressure may be equal or different from one another.

In some embodiments, reaction chambers 203A and 203 B may be dedicated to an infiltration process as described herein, or reaction chambers 203A and 203B may be used for other processes, e.g., for layer deposition and/or etch process. For example, reaction chambers 203A and 203B may comprise reaction chambers typically used for chemical vapor deposition (CVD) and/or atomic layer deposition processes, as described herein. In additional embodiments, the apparatus 300 may comprise additional reaction chambers for performing additional dedicated processes such as trimming, deposition and etch process.

As illustrated in FIG. 3, sources 207, 208, 210 and 216 are in fluid communication with reactor 302 via valves 211, 212, 214 and 218, which may be used to control the flow, mixing and distribution of the respective source materials to reactor chambers 203A and 203B using the supply lines 219, 220, 222 and 224.

A potential application for use of a combined annealing, infiltration process and removal of at least a portion of the first layer may be for extreme ultraviolet (EUV) photoresist. The annealing for a EUV application may not be for the self-assembly of the polymer, but may serve a curing or stabilizing purpose. For example, the combined annealing and infiltration process in accordance with at least one embodiment of the invention may assist in the sequential infiltration synthesis (SIS) step as potentially preventing conversion of carboxyl groups, or by degassing moisture from the polymer film or by stabilizing or hardening the photoresist.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof

What is claimed is:

1. A semiconductor processing apparatus configured to form a structure, the apparatus comprising:
a first reaction chamber, the first reaction chamber configured to hold at least one substrate having a first layer;
a precursor delivery system, the precursor delivery system configured to perform an infiltration by sequentially pulsing a first precursor and a second precursor onto the first layer, to enable infiltration of, and reaction between at least the first precursor and the second precursor in the first layer, thereby forming an infiltrated material; and
a first removal system configured for removing at least a portion of the first layer disposed on the substrate while leaving the infiltrated material; and
wherein the infiltration and the removing at least a portion of the first layer take place within the same semiconductor processing apparatus.

2. The apparatus of claim 1, further comprising a plasma generator configured to generate plasma activated species from an etchant gas supplied from the first removal system.

3. The apparatus of claim 1, wherein the first removal system further comprises a heating element configured to heat the at least one substrate to a temperature of greater than 450° C.

4. The apparatus of claim 1, wherein the first reaction chamber is configured for removing at least a portion of the first layer.

5. The apparatus of claim 4, wherein the first reaction chamber is configured to perform the annealing step.

6. The apparatus of claim 1, wherein the first reaction chamber is configured to process multiple substrates.

7. The apparatus of claim 1, wherein the precursor delivery system is further configured to perform a film deposition by sequentially pulsing a first precursor and a second precursor onto the infiltrated material.

8. The apparatus of claim 1, wherein the apparatus is further configured to perform an etching process to remove at least a portion of the substrate.

9. The apparatus of claim 8, further comprising a plasma generator configured to generate plasma activated etchant species from an etchant gas supplied from an etchant gas source.

10. The apparatus of claim 1, wherein the structure comprises at least one of aluminum oxide (Al₂O₃), silicon dioxide, (SiO₂), silicon nitride (SiN), silicon oxynitride (SiON), silicon carbonitride (SiCN), silicon (Si), aluminum nitride (AlN), titanium nitride (TiN), titanium carbide (TiC), tantalum nitride (TaN), tungsten (W), cobalt (Co), titanium dioxide (TiO₂), tantalum oxide (Ta₂O₅), zirconium dioxide (ZrO₂), or hafnium dioxide (HfO₂).

11. The apparatus of claim 1, wherein the first reaction chamber performs the infiltration and the second reaction chamber performs the removing at least a portion of the first layer.

12. The apparatus of claim 11, wherein the at least one substrate is transferred from the first reaction chamber to the second reaction along with at least a second substrate in a multiple substrate holder.

13. The apparatus of claim 1, wherein the first reaction chamber comprises a batch reactor.

14. The apparatus of claim 1, wherein the first reaction chamber comprises a single-wafer reactor.

15. The apparatus of claim 1, wherein the first removal system is further configured for performing a trimming process.

16. A semiconductor processing apparatus configured to form a structure, the apparatus comprising:
a first reaction chamber provided with a first substrate holder and configured and arranged to perform an infiltration of a first layer on a substrate positioned on the first substrate holder to infiltrate an infiltrated material into the first layer;
a second reaction chamber provided with a second substrate holder and configured and arranged to remove at least a portion of the first layer on the substrate positioned on the second substrate holder while leaving the infiltrated material on the substrate;
a substrate handler constructed and arranged to provide the substrate to the first substrate holder, to transfer the substrate from the first substrate holder to the second substrate holder and to remove the substrate from the second substrate holder; and
a housing covering the substrate handler and the first reaction chamber and the second reaction chamber to protect the substrate from an environment outside the apparatus during the transfer of the substrate from the first substrate holder to the second substrate holder.

17. A method of forming a structure within a semiconductor processing apparatus according to claim 1, the method comprising:
providing a substrate for processing in the reaction chamber, the substrate having a first layer disposed on the substrate;
performing a first layer infiltration by sequentially pulsing the first precursor and the second precursor onto the substrate, the first layer infiltration being configured to enable infiltration of at least the first precursor and the second precursor into the first layer, wherein an excess of the first precursor and the second precursor are purged from the reaction chamber; and
wherein an infiltrated material forms in the first layer from the reaction of the first precursor and the second precursor; and
removing at least a portion of the first layer disposed on the substrate after performing the infiltration while leaving the infiltrated material;
wherein the infiltration and the removing at least a portion of the first layer take place within the same semiconductor processing apparatus.

18. The method of claim 17, further comprising performing an annealing step on the substrate.

19. The method of claim 17, further comprising, performing at least one of a deposition process or an etching process on the substrate after removing at least a portion of the first layer disposed on the substrate.

20. The method of claim 17, wherein removing at least a portion of the first layer further comprises, exposing the first layer to an oxygen containing reactant.

21. The method of claim 17, wherein the structure comprises at least one of: aluminum oxide (Al₂O₃), silicon dioxide (SiO₂), silicon nitride (SiN), silicon (Si), silicon oxynitride (SiON), silicon carbonitride (SiCN), aluminum nitride (AlN), titanium nitride (TiN), titanium carbide (TiC), tantalum nitride (TaN), tungsten (W), cobalt (Co), titanium dioxide (TiO₂), tantalum oxide (Ta₂O₅), zirconium dioxide (ZrO₂), or hafnium dioxide (HfO₂).

22. The method of claim 18, wherein during the annealing step, a temperature of the reaction chamber ranges between 100° C. and 450° C.

23. The method of claim 17, wherein during the infiltration, the temperature of the reaction chamber ranges between 25° C. and 450° C.

24. The method of claim 17, wherein the first layer comprises at least one of:
a spin-on-glass, a spin-on-carbon layer, a silicon nitride layer, an anti-reflective-coating layer, or an amorphous carbon layer.

25. The method of claim 17, wherein the first layer comprises at least one of:
poly(methyl methacrylate) (PMMA), polystyrene, poly(styrene-block-methyl methacrylate) (PS-b-PMMA), a deep UV photoresist, 193 photoresist, 193i photoresist, or an extreme UV photoresist.

26. The method of claim 17, wherein the performing the infiltration is repeated in order to form the structure of a desired thickness.

27. The method of claim 17, wherein the infiltration comprises:
pulsing the first precursor onto the substrate;
purging the first precursor from the reaction chamber;
pulsing the second precursor onto the substrate; and
purging the second precursor from the reaction chamber.

28. The method of claim 18, wherein the annealing step and the infiltration take place within a single reaction chamber.

29. The method of claim 18, wherein the annealing step and the infiltration take place within different reaction chambers located on the semiconductor processing apparatus.

30. The method of claim 18, further comprising performing a trimming process prior to performing the first layer infiltration.

31. A method of forming a structure within a semiconductor processing apparatus according to claim 16, wherein the method comprises:
providing a substrate for processing in the first reaction chamber, the substrate having a first layer disposed on the substrate;
infiltrating the first layer with an inorganic material formed by gas-phase infiltration:
transferring the substrate from the first reaction chamber to the second reaction chamber, without exposing the first layer comprising an inorganic material to an environment outside the apparatus; and
removing at least a portion of the first layer in the second reaction chamber of the semiconductor processing apparatus while leaving the inorganic material on the substrate.
